(19) United States
(12) Patent Application Publication
(10) Pub. No.: US 2025/0316926 A1
(43) Pub. Date: Oct. 9, 2025

(54) CONNECTOR ASSEMBLY

(71) Applicant: Molex, LLC, Lisle, IL (US)

(72) Inventor: Chen-Min LIN, New Taipei City (TW)

(21) Appl. No.: 19/173,214

(22) Filed: Apr. 8, 2025

(30) Foreign Application Priority Data
Apr. 8, 2024 (CN) 202410414752.6

(51) Int. Cl. H01R 13/533; H01R 13/6581

(52) U.S. Cl. CPC H01R 13/533; H01R 13/6581

(57) ABSTRACT

A connector assembly includes a shielding shell, a heat sink bracket, a snapping construction and a locking construction. The shielding shell includes at least one inserting passageway, a top wall which corresponds to the inserting passageway, and a mounting portion which is provided to the top wall; the heat sink bracket is allowed to be mounted to the mounting portion of the top wall, the heat sink bracket includes a side frame portion and a bottom frame portion. The snapping construction is provided to the side frame portion of the heat sink bracket and the mounting portion of the top wall and allows the side frame portion of the heat sink bracket to be assembled to the mounting portion. The locking construction includes a first locking member which is provided to the bottom frame portion of the heat sink bracket and a second locking member which is provided to the mounting portion, the first locking member comprising an elastic arm and a locking portion and a locking release portion which are provided to the elastic arm, the locking portion of the first locking member locks to the second locking member, the locking release portion is capable of being operated to make the locking portion leave the second locking member.

### TECHNICAL FIELD

The present disclosure relates to a connector assembly, and particularly relates to a connector assembly assembled with a heat sink.

### BACKGROUND

Chinese patent document CN114623722A (corresponding to United State patent document US2022/0190506A1) discloses a heat sink module, which includes a heat dissipating member, a pressure applying elastic member, a lever member and a supporting elastic member. In the heat dissipating module, an upper heat dissipating module is received in an upper heat sink bracket, a design of the upper heat sink bracket is with respect to assembling on a guide shielding cage which has a single inserting passageway, insertion pieces of two side walls of the upper heat sink bracket need extend downwardly and rearwardly to side walls of the guide shielding cage respectively so as to respectively insert insertion grooves. Moreover, a rear end of a lower wall of the upper heat sink bracket has a latching piece which may latch into a latching groove of a top wall of the guide shielding cage when assembled, however, due to a relationship different from a direction that the insertion piece inserts into the insertion groove, when the upper heat sink bracket needs to be detached, it is not easy to make the latching piece leave the latching groove. Based on the aforementioned consideration, with respect to a guide shielding cage which has a plurality of inserting passageways, in order to receive a plurality of heat sink modules, a construction of a heat sink bracket needs to be redesigned.

### SUMMARY

Therefore, an object of the present disclosure is to provide a connector assembly having a heat sink bracket which is more easily assembled and detached.

Another object of the present disclosure is to provide a connector assembly having a heat sink bracket which is designed with respect to a plurality of inserting passageways.

Accordingly, a connector assembly of the present disclosure comprises a shielding shell, a heat sink bracket, a snapping construction and a locking construction. The shielding shell comprises at least one inserting passageway, a top wall which corresponds to the inserting passageway, and a mounting portion which is provided to the top wall; the heat sink bracket is allowed to be mounted to the mounting portion of the top wall, the heat sink bracket comprises a side frame portion and a bottom frame portion. The snapping construction is provided to the side frame portion of the heat sink bracket and the mounting portion of the top wall and allows the side frame portion of the heat sink bracket to be assembled to the mounting portion. The locking construction comprises a first locking member which is provided to the bottom frame portion of the heat sink bracket and a second locking member which is provided to the mounting portion, the first locking member comprising an elastic arm and a locking portion and a locking release portion which are provided to the elastic arm, the locking portion of the first locking member locks to the second locking member, the locking release portion is capable of being operated to make the locking portion leave the second locking member.

In some embodiments, the elastic arm is a cantilevered elastic plate structure, is positioned to a rear end of the bottom frame portion of the heat sink bracket and extend rearwardly.

In some embodiments, the locking portion is formed to the elastic arm by the elastic arm being stamped to protrude downwardly, the locking release portion is a levering piece which extends from the elastic arm obliquely in a lateral direction of the elastic arm and in an up-down direction, the levering piece and the top wall of the shielding shell form an inserting space therebetween.

In some embodiments, the snapping construction comprises a first snapping member which is provided to the side frame portion of the heat sink bracket, and a second snapping member which is provided to the mounting portion, the first snapping member is capable of snapping to the second snapping member along a snapping direction which is in a front-rear direction so as to make the second snapping member provide position-limiting to the heat sink bracket both in an up-down direction and in the snapping direction.

In some embodiments, the second snapping member is positioned to an outer side of the side frame portion of the heat sink bracket, and is positioned to an outer side of the first snapping member, the second snapping member provides position-limiting to the heat sink bracket in a left-right direction.

In some embodiments, the mounting portion comprises two side portions which are respectively positioned left and right, the first snapping member comprises a plurality of snapping protrusions which protrude outwardly from the side frame portion of the heat sink bracket, the second snapping member comprises a plurality of snapping pieces which extend upwardly from each side portion of the mounting portion, each snapping piece has a snapping groove opened toward the front, each snapping protrusion rearwardly snaps into the snapping groove of the snapping piece.

In some embodiments, each snapping groove has an inner top edge and an inner bottom edge, and the inner top edge and the inner bottom edge are staggered with each other in the left-right direction, so that when the snapping protrusion inserts into the snapping groove of the snapping piece, positions that the inner top edge and the inner bottom edge abut against the snapping protrusion are staggered with each other in the left-right direction.

In some embodiments, the heat sink bracket comprises the two side frame portions which are respectively positioned left and right, positions of the first snapping members, which are positioned to the two side frame portions of the heat sink bracket, are staggered with each other in the left-right direction.

In some embodiments, the heat sink bracket is used to receive a heat sink and further comprises a top frame portion, the top frame portion comprises two supporting frame borders which are spaced apart from each other and cooperate to define an upper frame mouth, and a transverse frame bar which connects the two supporting frame borders, the upper frame mouth allows the heat sink to upwardly extend out therefrom, the transverse frame bar is positioned between a plurality of heat dissipating fins of the heat sink, and is used to limit a position of the heat sink in a front-rear direction.

In some embodiments, the side frame portion of the heat sink bracket is provided with apertures, the apertures correspond to airflow passageways between heat dissipating fins of the heat sink.

In some embodiments, the side frame portion of the heat sink bracket is provided with a plurality of guiding protrusions which are toward the down, a side portion of the mounting portion is provided with elongated guiding holes which each allows to the respective guiding protrusion to enter therein, and a length of each elongated guiding hole in the front-rear direction is larger than the respective guiding protrusion.

An effect of the present disclosure lies in that, provision of the first locking member and the second locking member of the locking construction makes locking and releasing of the locking construction not be limited by the assembling and detaching direction of the snapping member, so that the heat sink bracket is more easily assembled and detached, moreover, provision of the first snapping members and the second snapping members of the snapping construction also make the heat sink bracket adapted to the shielding shell which has a plurality of inserting passageways and needs to be assembled with a plurality of heat sink brackets.

A connector assembly of the present disclosure comprises a heat sink bracket and a position-limiting structure. The heat sink bracket is assembled by an upper bracket and a lower bracket, the upper bracket comprises a top plate and two first side plates which are respectively positioned left and right, the lower bracket comprises a bottom plate and two second side plates which are respectively positioned left and right, the top plate of the upper bracket constitutes a top frame portion of the heat sink bracket, the bottom plate of the lower bracket constitutes a bottom frame portion of the heat sink bracket, each first side plate of the upper bracket and the corresponding second side plate of the lower bracket overlap with each other and constituting one side frame portion of the heat sink bracket. The position-limiting structure comprises a first position-limiting portion and a second position-limiting portion which are provided to each first side plate of the upper bracket and a third position-limiting portion and a fourth position-limiting portion which are provided to each second side plate of the lower bracket, the first position-limiting portion and the third position-limiting portion provide position-limiting in a first direction, the second position-limiting portion and the fourth position-limiting portion provide position-limiting in a second direction.

In some embodiments, in the first side plate and the second side plate which overlap with each other, the first side plate is positioned outside, the second side plate is positioned inside, the first position-limiting portion comprises a latching hole which is provided to the first side plate, the third position-limiting portion comprises a latching protrusion which is provided to the second side plate.

In some embodiments, the first position-limiting portion comprises the two latching holes which are provided respectively in the front of the first side plate and at the rear of the first side plate, the third position-limiting portion comprises the two latching protrusions which are provided respectively in the front of the second side plate and at the rear of the second side plate and respectively correspond to the two latching holes, each latching hole is larger than the corresponding latching protrusion, a front edge and a bottom edge of the latching hole which is positioned in the front of the first side plate is capable of being limited in position by the corresponding latching protrusion, and a rear edge and a bottom edge of the latching hole which is positioned at the rear of the first side plate is capable of being limited in position by the corresponding latching protrusion, thereby providing position-limiting both in a front-rear direction and in an up-down direction.

In some embodiments, the first side plate is positioned outside, the second side plate is positioned inside, the second position-limiting portion comprises a depressed portion which is positioned to the first side plate and is depressed inwardly, the fourth position-limiting portion comprises a protruding portion which is positioned to the second side plate, the protruding portion is constructed on an upper edge of a protruding part, which is outward, of the second side plate and extends upwardly, the protruding portion enters into the depressed portion, the protruding portion is positioned to an outer side of the depressed portion in a left-right direction and the protruding portion and the depressed portion stop each other in the left-right direction.

In some embodiments, the position-limiting structure further comprises a stopping tab which is provided to the upper bracket, the stopping tab extends downwardly from the top plate of the upper bracket and is positioned to an inner side of the first side plate, so that a top edge of the second side plate is positioned between the first side plate and the stopping tab, thereby providing position-limiting of an upper end of the second side plate in a left-right direction.

In some embodiments, the connector assembly further comprises a shielding shell, the shielding shell comprises at least one inserting passageway, a top wall which corresponds to the inserting passageway, and a mounting portion which is provided to the top wall; each side frame portion of the heat sink bracket and the mounting portion are provided therebetween with a first snapping member and a second snapping member which cooperate with each other; the bottom plate of the lower bracket and the mounting portion are provided therebetween with a first locking member and a second locking member which cooperate with each other.

In some embodiments, the first locking member comprises an elastic arm and a locking portion and a locking release portion which are provided to the elastic arm, the locking portion of the first locking member locks to the second locking member, the locking release portion is capable of being operated to make the locking portion leave the second locking member.

An effect of the present disclosure lies in that, based on assembling of the upper bracket and the lower bracket of the heat sink bracket, provision of the position-limiting structure provides position-limiting of the upper bracket and the lower bracket in various directions, which achieves to increase an assembling strength between the upper bracket and the lower bracket and provide a firmly assembled structure.

### BRIEF DESCRIPTION OF THE DRAWINGS

Other features and effects of the present disclosure will be apparent from an embodiment with reference to the drawings, in which:

FIG. 1 is a perspective view illustrating that an embodiment of a connector assembly of the present disclosure can allow a connector to mate therewith;

FIG. 2 is an exploded view illustrating that the connector assembly includes a shielding shell and a plurality of heat sink brackets and each heat sink bracket can allow a heat sink to provided thereto;

FIG. 3 is an exploded view illustrating that the shielding shell of the connector assembly includes a top wall, a bottom wall and a plurality of partitioning walls;

FIG. 4 is an exploded view illustrating that the heat sink bracket of the connector assembly is assembled by an upper bracket and a lower bracket, with the heat sink and a part of the top wall of the shielding shell shown;

FIG. 5 is an assembled view of FIG. 4 and illustrates a state that the upper bracket and the lower bracket are assembled and are engaged to the top wall of the shielding shell;

FIG. 6 is a perspective view illustrating a structure of a bottom portion of the heat sink bracket;

FIG. 7 is a partial perspective view illustrating cooperation between a second position-limiting portion and a fourth position-limiting portion of a position-limiting structure;

FIG. 8 is a partial perspective view illustrating a state that the heat sink bracket is assembled to the top wall of the shielding shell;

FIG. 9 is a partial perspective view from another angle illustrating the state that the heat sink bracket is assembled to the top wall of the shielding shell;

FIG. 10 is a partial perspective view illustrating that a snapping construction of the connector assembly includes a first snapping member and a second snapping member;

FIG. 11 is a partial perspective view illustrating a state that the heat sink is provided to the heat sink bracket; and

FIG. 12 is an exploded view illustrating heat dissipating fins and a base of the heat sink.

Reference numerals are presented as follows.
1 shielding shell
10 slot
11 inserting passageway
12 top wall
13 mounting portion
131 opening
132 side portion
133 elongated guiding hole
14 bottom wall
15 partitioning wall
2 heat sink bracket
21 top frame portion
211 upper frame mouth
212 supporting frame border
213 transverse frame bar
22 side frame portion
23 bottom frame portion
24 upper bracket
241 top plate
242 first side plate
243 guiding protrusion
25 lower bracket
251 bottom plate
252 second side plate
253 opening
3 snapping construction
31 first snapping member
311 snapping protrusion
32 second snapping member
321 snapping piece
322 snapping groove
323 inner top edge
324 inner bottom edge
325 local plate piece
4 locking construction
40 channel
41 first locking member
410 inserting space
411 elastic arm
412 locking portion
413 locking release portion
42 second locking member
5 connector
6 heat sink
61 heat dissipating fin
62 base
63 pressing member
631 front end
632 rear end
64 pressing spring
65 contacting spring
7 position-limiting structure
71 first position-limiting portion
71a, 71b latching hole
72 second position-limiting portion
720 depressed portion
721 stopping hole
723 stopping piece
73 third position-limiting portion
73a, 73b latching protrusion
74 fourth position-limiting portion
741 protruding part
742 protruding edge
75 stopping tab
D snapping direction

### DETAILED DESCRIPTION

Before the present disclosure is described in detail, it is noted that the similar elements are indicated by the same reference numerals in the following described content.

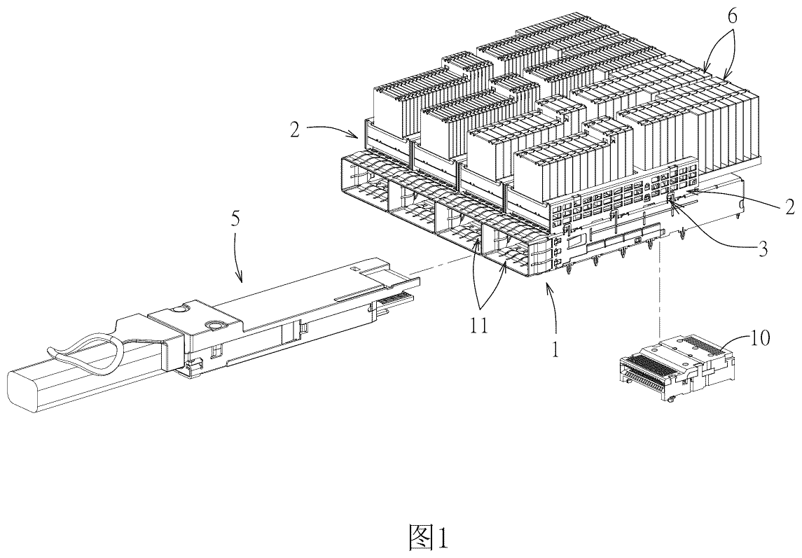

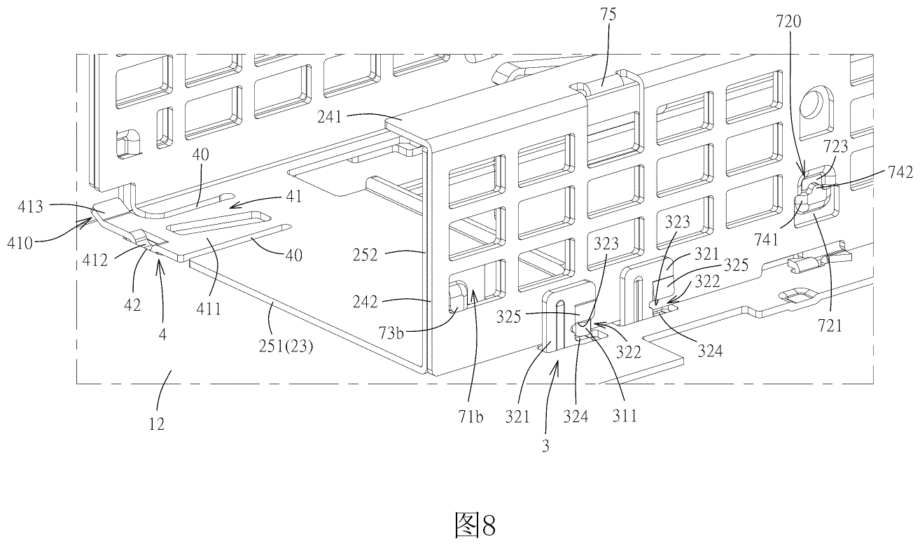

Referring to FIG. 1 to FIG. 3, an embodiment of a connector assembly of the present disclosure includes a shielding shell 1, a plurality of heat sink brackets 2, a snapping construction 3 and a locking construction 4 (see FIG. 8), the shielding shell 1 can allow a connector 5 to insert therein, each heat sink bracket 2 allows a heat sink 6 to be provided thereto.

The shielding shell 1 includes at least one inserting passageway 11, a top wall 12 which corresponds to the inserting passageway 11, and a mounting portion 13 which is provided to the top wall 12. In the present embodiment, besides the top wall 12, the shielding shell 1 further includes a bottom wall 14 which is used to be engaged with the top wall 12 up and down, and a plurality of partitioning walls 15 which are provided between the top wall 12 and the bottom wall 14, the aforementioned mounting portion 13 are the plurality of mounting portions 13 and the plurality of mounting portions 13 are provided to the top wall 12, each mounting portion 13 includes an opening 131 which is communicated with the inserting passageway 11 and two side portions 132 which are respectively positioned to a left side and a right side of the opening 131, the plurality of partitioning walls 15 are assembled between the top wall 12 and the bottom wall 14 and partition the plurality of the inserting passageways 11, a rear end of each inserting passageway 11 is provided with a slot 10 which can allow a connector 5, which inserts into the inserting passageway 11, to mate therewith, and each inserting passageway 11 corresponds to one mounting portion 13 on the top wall 12, so in an implementing manner that the at least one inserting passageway 11 is one inserting passageway 11, the aforementioned mounting portion 13 on the top wall 12 also is one mounting portion 13.

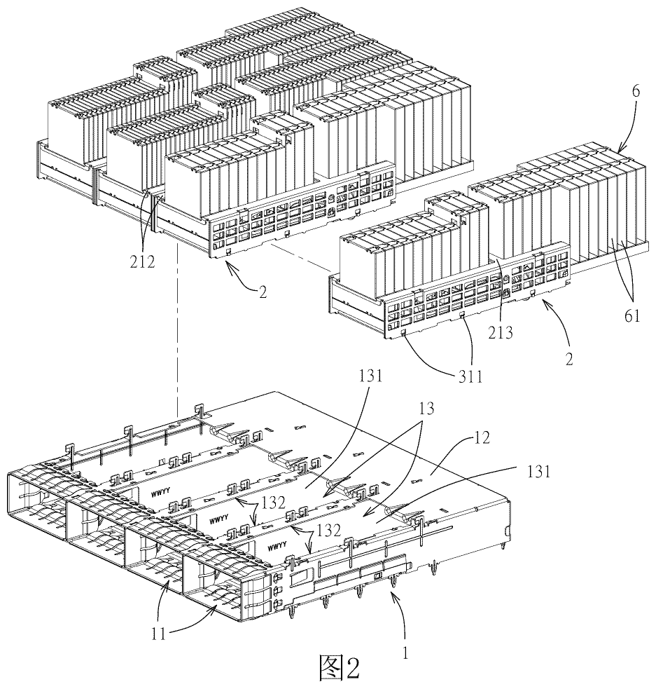

Referring to FIG. 2 and FIG. 4 to FIG. 6, the heat sink bracket 2 is allowed to be mounted to the mounting portion 13 of the top wall 12 of the shielding shell 1. Each heat sink bracket 2 includes a top frame portion 21, two side frame portions 22 and a bottom frame portion 23. The top frame portion 21 includes two supporting frame borders 212 which are spaced apart from each other left and right and cooperate to define an upper frame mouth 211, and a transverse frame bar 213 which connects the two supporting frame borders 212, when the heat sink 6 is provided to the heat sink bracket 2, the upper frame mouth 212 allows the heat sink 6 to upwardly extend out thereof, the supporting frame borders 212 of the two adjacent heat sink brackets 2 which are arranged side by side approach each other and are arranged side by side, and the transverse frame bar 213 is positioned between a plurality of heat dissipating fins 61 of the heat sink 6 and is used to limit a position of the heat sink 6 in a front-rear direction. In the present embodiment, the heat sink bracket 2 is assembled by an upper bracket 24 and a lower bracket 25. The upper bracket 24 includes a top plate 241 and two first side plates 242 which are respectively positioned left and right and extend downwardly from the top plate 241, the lower bracket 25 includes a bottom plate 251 and two second side plates 252 which are respectively positioned left and right and extends upwardly from the bottom plate 251, the top plate 241 of the upper bracket 24 constitutes the aforementioned top frame portion 21, so the upper frame mouth 211, the two supporting frame borders 212 and the transverse frame bar 213 as aforementioned are positioned to the top frame portion 21, the bottom plate 251 of the lower bracket 25 constitutes the aforementioned bottom frame portion 23, and the bottom plate 251 also is provided with an opening 253, when the upper bracket 24 and the lower bracket 25 are engaged with each other up and down, the first side plate 242 of the upper bracket 24 and the second side plate 252 of the lower bracket 25 which are positioned to the same side overlap with each other and constitute one side frame portion 22 of the heat sink bracket 2, and in the one side frame portion 22, the first side plate 242 of the upper bracket 24 is positioned outside and the second side plate 252 of the lower bracket 25 is positioned inside.

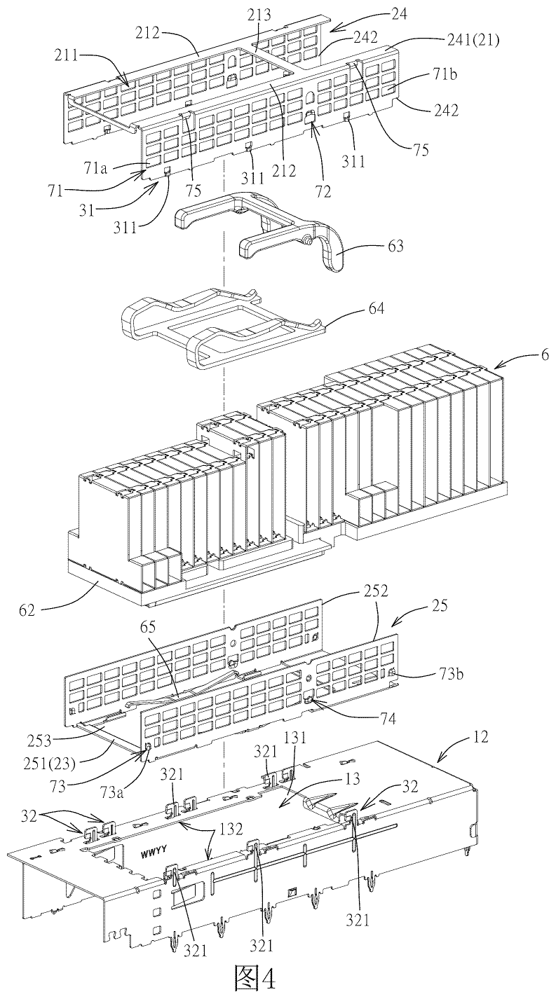

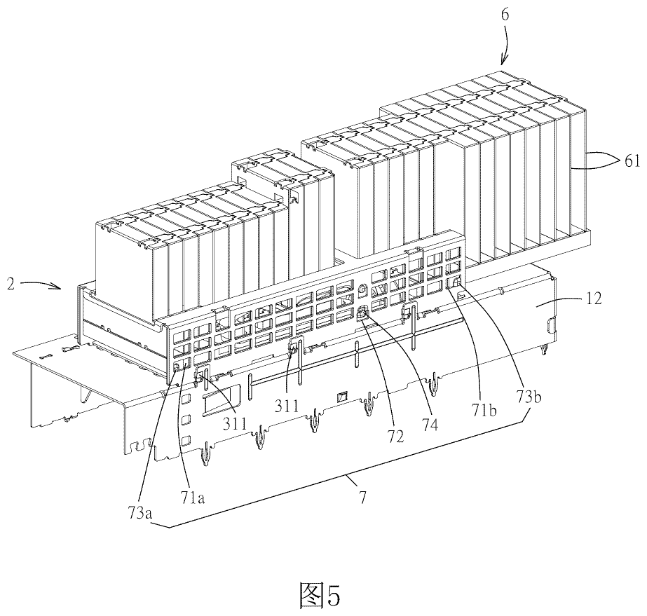

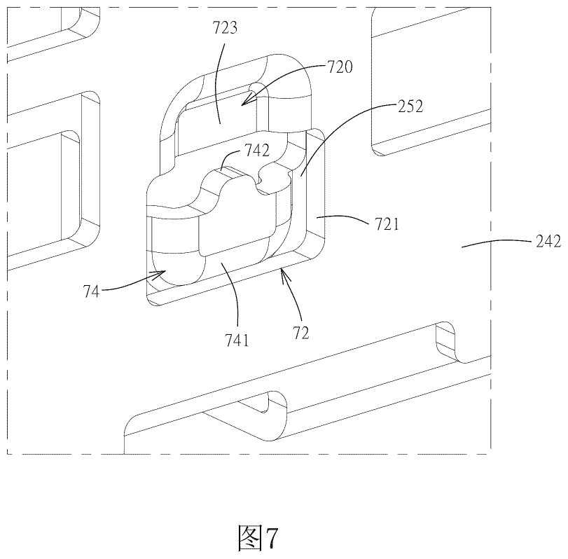

Referring to FIG. 4 to FIG. 7, in order to achieve assembling of the upper bracket 24 and the lower bracket 25, in the present embodiment, the connector assembly further includes a position-limiting structure 7 (see FIG. 5), the position-limiting structure 7 includes a first position-limiting portion 71 and a second position-limiting portion 72 which are provided to the first side plate 242 of the upper bracket 24, and a third position-limiting portion 73 and a fourth position-limiting portion 74 which are provided to the second side plate 252 of the lower bracket 25, the first position-limiting portion 71 and the third position-limiting portion 73 cooperate with each other to provide position-limiting in a first direction, the second position-limiting portion 72 and the fourth position-limiting portion 74 cooperate with each other to provide position-limiting in a second direction. In the present embodiment, the first position-limiting portion 71 includes two latching holes 71a, 71b which are respectively provided to a front bottom corner and a rear bottom corner of each first side plate 242, the third position-limiting portion 73 includes two latching protrusions 73a, 73b which are respectively provided to a front bottom corner and a rear bottom corner of each second side plate 252 and respectively correspond to the two latching holes 71a, 71b, and the latching hole 71a, 71b is larger than the latching protrusion 73a, 73b, when the first side plate 242 and the second side plate 252 correspondingly overlap with each other, a front edge and a bottom edge of the latching hole 71a which is positioned front can be abutted against by the corresponding latching protrusion 73a so as to, a rear edge and a bottom edge of the latching hole 71b which is positioned rear can be abutted against by the corresponding latching protrusion 73b so as to be limited in position, thereby, besides providing position-limiting of the first side plate 242 and the second side plate 252 in a front-rear direction, also in cooperation with an assembling direction of the upper bracket 24 and the lower bracket 25, providing position-limiting of the first side plate 242 and the second side plate 252 in an up-down direction, so the aforementioned first direction may be the front-rear direction. As for cooperation between the latching holes 71a, 71b and the latching protrusions 73a, 73b, in the present embodiment, the first side plate 242 and the second side plate 252 each are provided with a plurality of apertures which are arranged in matrix, and some of the apertures of the first side plate 242 and the second side plate 252 are correspondingly communicated with each other to cooperate with provided positions of the latching protrusions 73a, 73b, the apertures which are respectively positioned to the most front bottom corner and the most rear bottom corner of the first side plate 242 are the latching holes 71a, 71b respectively, the remainder of the apertures of the first side plate 242 and the second side plate 252 which are correspondingly communicated with each other may correspond to airflow passageways between the adjacent heat dissipating fins 61 of the heat sink 6, thereby providing heat dissipating effect.

The second position-limiting portion 72 includes a depressed portion 720 which is positioned to each first side plate 242 and is depressed inwardly, the fourth position-limiting portion 74 includes a protruding portion which is positioned to each second side plate 252, the protruding portion enters into the depressed portion 720, and the protruding portion is positioned to an outer side of the depressed portion 720 in the left-right direction and is stopped by the depressed portion 720 in the left-right direction. In the present embodiment, the second position-limiting portion 72 further includes a stopping hole 721 which is provided to each first side plate 242 and a stopping piece 723 which is positioned above the stopping hole 721, the stopping piece 723 is defined by that a region of the first side plate 242 which is positioned above the stopping hole 721 is inwardly stamped and depressed to form the aforementioned depressed portion 720, and, a length of the stopping hole 721 in the front-rear direction is larger than a length of the stopping piece 723. The fourth position-limiting portion 74 further includes a protruding part 741 which is provided to each second side plate 252. In the present embodiment, each protruding part 741 is formed by that a local region of the second side plate 252 is stamped outwardly to bulge, and the protruding part 741 has a protruding edge 742 which protrudes upwardly, that is, the aforementioned protruding portion, because the protruding part 741 bulges outwardly, the protruding edge 742 is spaced apart from an outer side of the second side plate 252, when the first side plate 242 and the second side plate 252 correspondingly overlap with each other, the protruding part 741 passes through the stopping hole 721 and the protruding edge 742 of the protruding part 741 upwardly enters into the depressed portion 720 and abuts against an outer side of the stopping piece 723, so that the stopping piece 723 is interposed between the second side plate 252 and the protruding edge 742, an interference relationship that the protruding part 741 passes through the stopping hole 721 provides position-limiting of the first side plate 242 and the second side plate 252 in the front-rear direction, and that the protruding edge 742 abuts against the outer side of the stopping piece 723 provides position-limiting of the first side plate 242 and the second side plate 252 in the left-right direction, so the aforementioned second direction also may be understood as the left-right direction.

In addition, the position-limiting structure 7 further includes a plurality of stopping tabs 75 which are provided to the upper bracket 24. In the present embodiment, each stopping tab 75 is formed by that a local region of the top plate 241 of the upper bracket 24 is torn to form a hole and a tongue-shaped structure and the tongue-shaped structure downwardly bends and extends to be positioned to an inner side of the first side plate 242, and a position of the stopping tab 75 is spaced apart from an inner side of remained region of the first side plate 242, when the first side plate 242 and the second side plate 252 correspondingly overlap with each other, a top edge of the second side plate 252 enters into and is positioned between the first side plate 242 and the stopping tab 75, thereby providing position-limiting of an upper end of the second side plate 252 in the left-right direction.

Therefore, as can be seen from the above content, in the present disclosure, the cooperation between the first position-limiting portion 71 and the third position-limiting portion 73 provides the position-limiting of the upper bracket 24 and the lower bracket 25 both in the front-rear direction and in the up-down direction, the cooperation between the second position-limiting portion 72 and the fourth position-limiting portion 74 provides the position-limiting in the left-right direction, the stopping tab 75 provides the position-limiting in the left-right direction.

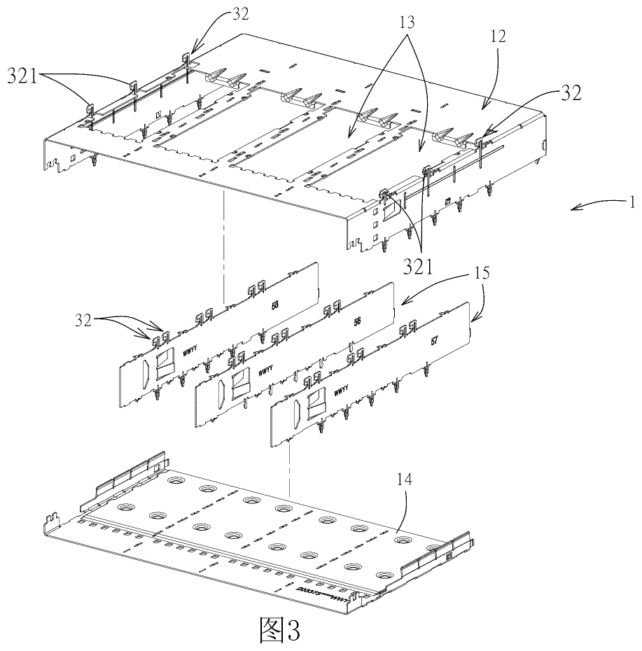

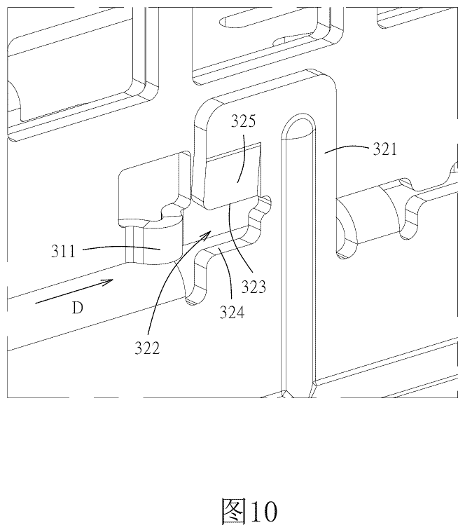

Referring to FIG. 3 to FIG. 5 and FIG. 8 to FIG. 10, each heat sink bracket 2 is assembled and engaged to the shielding shell 1 by the snapping construction 3 and the locking construction 4. Here, the snapping construction 3 includes a first snapping member 31 which is provided to the heat sink bracket 2, and a second snapping member 32 which is provided to the mounting portion 13 of the shielding shell 1, the first snapping member 31 is capable of snapping to the second snapping member 32 along a snapping direction (as shown by an arrow D of FIG. 10) which is in the front-rear direction, which makes the second snapping member 32 provide position-limiting to the heat sink bracket 2 both in the up-down direction and in the left-right direction, and which provides the heat sink bracket 2 to be assembled to the mounting portion 13. The first snapping member 31 includes a plurality of snapping protrusions 311 which protrude outwardly from each side frame portion 22 of the heat sink bracket 2. More specifically, the snapping protrusion 311 is formed by that a local region of the first side plate 242 of the upper bracket 24 is outwardly stamped to protrude from an outer surface of the first side plate 242, the plurality of snapping protrusions 311 are close to a bottom edge of the first side plate 242 and are arranged to be spaced apart from each other front and rear, and positions of the first snapping members 31 positioned to the two first side plates 242 are staggered with each other. And as for the second snapping member 32, the side portion 132 of each mounting portion 13 is provided with one second snapping member 32, each second snapping member 32 includes a plurality of snapping pieces 321 which extend upwardly from the side portion 132 of the mounting portion 13, each snapping piece 321 has a snapping groove 322 opened toward the front. As for a structure of the snapping piece 321, in the present embodiment, due to a relationship among the plurality of the mounting portions 13, as shown in FIG. 3, except that the snapping pieces 321 of the two second snapping members 32, which are positioned to the most left outer side and the most right outer side of the top wall 12 of the shielding shell 1, are integrally formed by the top wall 12 and extend upwardly, the snapping pieces 321 of the remained second snapping members 32 are formed to top edges of the plurality of partitioning walls 15, when the partitioning wall 15 is provided between the top wall 12 and the bottom wall 14, the snapping piece 321 upwardly extends out of the top wall 12 from a region of the top wall 12 which is close to the opening 131, and the top edge of each partitioning wall 15 is provided with the two second snapping members 32 which respectively provide the second snapping members 32 for the two side portions 132 of the two mounting portions 13 which are positioned at a left side and a right side of the partitioning wall 15, the snapping pieces 321 of the two second snapping members 32 positioned to the same the partitioning wall 15 are arranged front and rear, and in the present embodiment, corresponding to positions of the first snapping members 31 of the two first side plates 242 of the upper bracket 24, the second snapping members 32 of the two side portions 132 of the same mounting portion 13 are staggered with each other in the left-right direction, so that snapping positions at a left side and a right side of the heat sink bracket 2 are more uniformly distributed and the heat sink bracket 2 is stabler.

Further, in the present embodiment, the snapping groove 322 of the snapping piece 321 of each second snapping member 32 has an inner top edge 323 and an inner bottom edge 324, and in the present embodiment, by that a local plate piece 325 of the snapping piece 321, which defines the inner top edge 323, bends obliquely toward the inserting passageway 11, the inner top edge 323 and the inner bottom edge 324 are staggered with each other in the left-right direction, whose function will be described later.

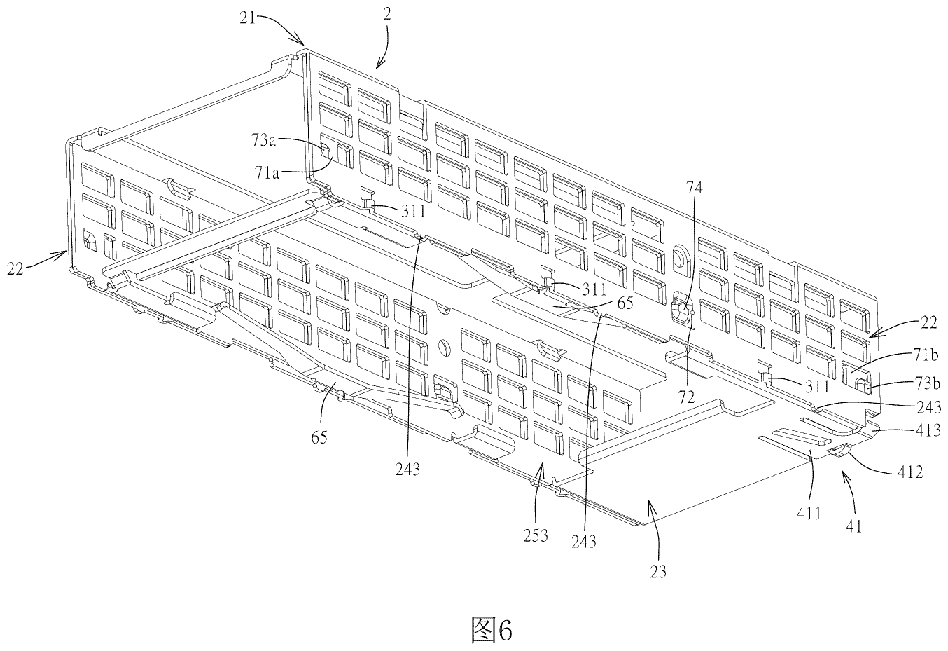

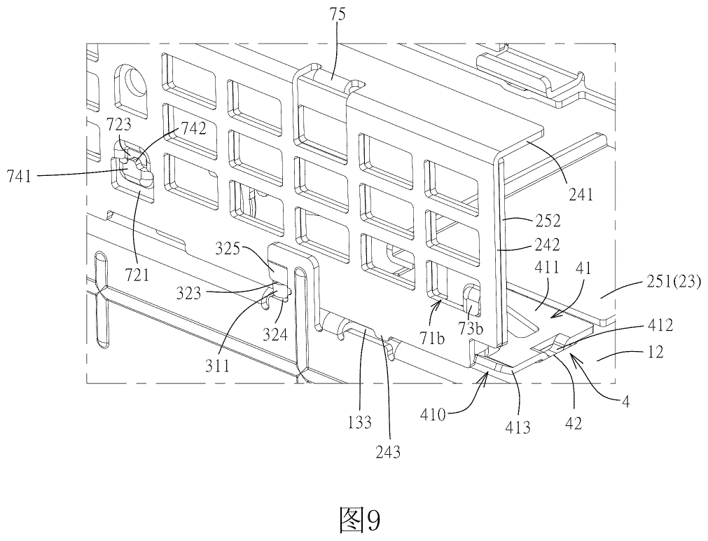

Referring to FIG. 6, FIG. 8 and FIG. 9, the locking construction 4 includes a first locking member 41 which is provided to the bottom frame portion 23 of the heat sink bracket 2, and a second locking member 42 which is provided to the mounting portion 13. The first locking member 41 includes an elastic arm 411, and a locking portion 412 and a locking release portion 413 which are provided to the elastic arm 411. The clastic arm 411 is defined by a local region of the bottom frame portion 23 is provided with a channel 40 to form an elastic plate, the elastic arm 411 is an cantilevered elastic plate and is positioned to a rear end and of the bottom frame portion 23 of the heat sink bracket 2 and extends rearwardly, and is capable of being elastically deformed up and down relative to the bottom frame portion 23. The locking portion 412 is formed by a local region of the elastic arm 411 is stamped to protrude downwardly. The locking release portion 413 is a levering piece which extends from the elastic arm 411 obliquely in a lateral direction of the elastic arm 411 and in the up-down direction. In the present embodiment, the second locking member 42 is a locking hole which is provided to the top wall 12, is positioned behind the opening 131 of the mounting portion 13, and penetrates the top wall 12. The levering piece extending obliquely is used to form an inserting space 410 together with the top wall 12 of the shielding shell 1 therebetween when the locking portion 412 is locked to the locking hole.

When the heat sink bracket 2 is assembled to the top wall 12 of the shielding shell 1, firstly the heat sink bracket 2 is positioned between the two side portions 13 of the mounting portion 13, next, the snapping protrusions 311 of the first snapping members 31 of the two side frame portions 22 of the heat sink bracket 2 rearwardly snap into the snapping grooves 322 of the corresponding second snapping members 32 respectively, the snapping between the first snapping members 31 and the second snapping members 32 provide positioning of the heat sink bracket 2 and the shielding shell 1 both in the left-right direction and in the up-down direction, and here, by that the inner top edge 323 and the inner bottom edge 324 of each snapping groove 322 are staggered with each other in the left-right direction, positions that the inner top edge 323 and the inner bottom edge 324 of each snapping groove 322 abut against the snapping protrusion 311 are staggered with each other in the left-right direction, stability of snapping between the first snapping member 31 and the second snapping member 32 may be promoted. Moreover, that the locking portion 412 of the first locking member 41 snaps into the locking hole of the second locking member 42 provides positioning of the heat sink bracket 2 and the shielding shell 1 in the front-rear direction.

And it is noted that, because the locking release portion 413 of the first locking member 41 is the levering piece which is obliquely provided to form the inserting space 410 together with the top wall 12 of the shielding shell 1 therebetween, when locking of the first locking member 41 and the second locking member 42 needs to be released, the locking release portion 413 is upwardly levered by a finger, or the locking release portion 413 is upwardly pried by a tool which inserts into inserting space 410, the locking portion 412 may upwardly leave the second locking member 42, next, the heat sink bracket 2 is moved to make the snapping protrusions 311 of the first snapping members 31 respectively withdraw out from the snapping grooves 322 of the second snapping members 32, that is, the heat sink bracket 2 may be separated from the shielding shell 1.

Besides the aforementioned structure, in the present embodiment, the side frame portion 22 of the heat sink bracket 2 is further provided with a plurality of guiding protrusions 243 which are toward the down, each side portion 132 of the mounting portion 13 is provided with elongated guiding holes 133 which each allow the respective guiding protrusion 243 to enter therein, and a length of the elongated guiding hole 133 in the front-rear direction is larger than the guiding protrusion 243, provision of the guiding protrusion 243 and the elongated guiding hole 133 provides guiding of the heat sink bracket 2 assembled to the shielding shell 1.

Therefore, in the present disclosure, by provision of the first locking member 41 and the second locking member 42 and by that the elastic arm 411 is a plate piece which is independent movable, when the locking relationship between the first locking member 41 and the second locking member 42 is released, it does not need to be limited by the assembling and detaching direction of the first snapping member 31 and the second snapping member 32, in comparison with the prior art, the first locking member 41 and the second locking member 42 are indeed more easily to assemble and detach, moreover, the structure and the cooperating manner of the first snapping member 31 and the second snapping member 32 are also adapted to a structure manner of the shielding shell 1 which has a plurality of inserting passageways 11.

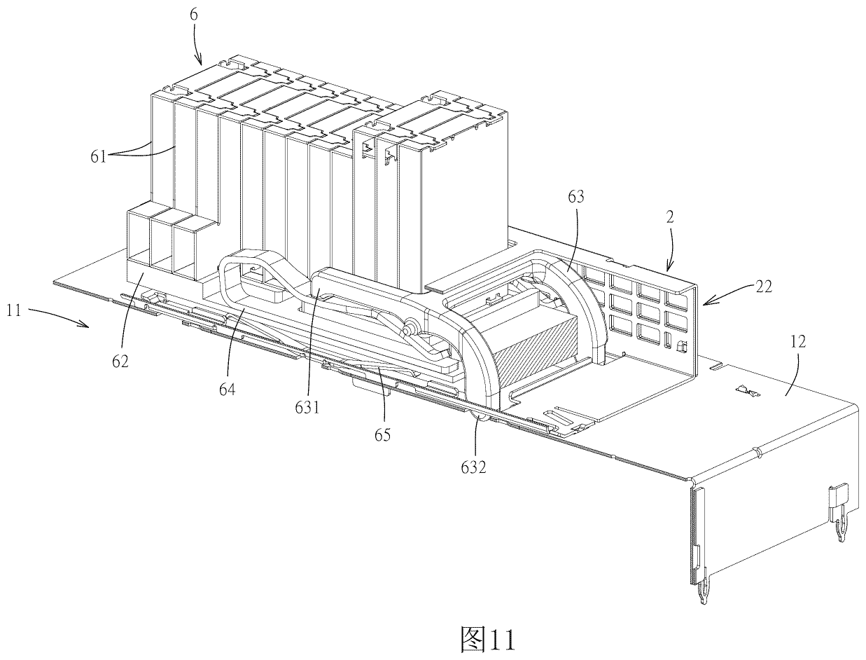

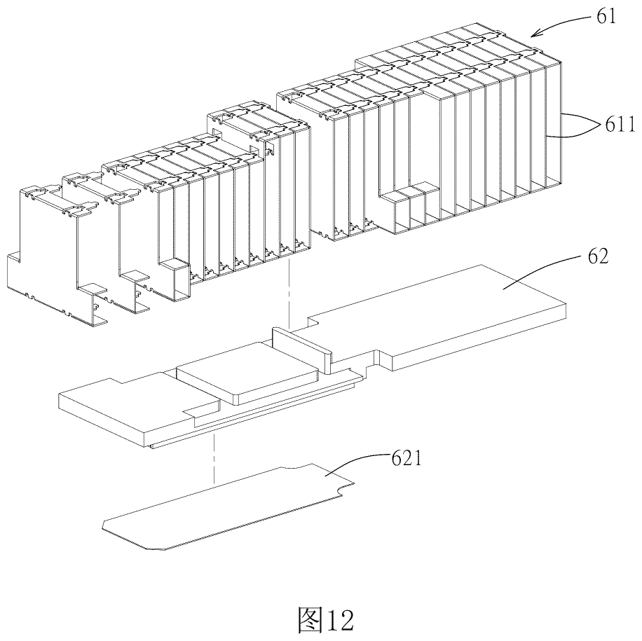

Referring to FIG. 4, FIG. 6, FIG. 11 and FIG. 12, in the present embodiment, besides that the heat sink 6 includes the plurality of heat dissipating fins 61 which latch with each other, the heat sink 6 further includes a base 62, a pressing member 63, a pressing spring 64 and two contacting springs 65, and a bottom portion of the base 62 is provided with a thermal conductive pad 621. The plurality of heat dissipating fins 61 are provided on the base 62, and the base 62 enters into the inserting passageway 11 via the opening 253 of the bottom plate 251 of the lower bracket 25 of the heat sink bracket 2 and the opening 131 of the mounting portion 13 of the top wall 12 of the shielding shell 1 to be capable of contacting a connector 5 which inserts into the inserting passageway 11, the pressing member 63 has a front end 631 which is toward the front and a rear end 632 which is toward the down and the pressing member 63 is pivoted to the two side frame portions 22 of the heat sink bracket 2 between the front end 631 and the rear end 632, the rear end 632 of the pressing member 63 enters into the inserting passageway 11 via the opening 253 of the bottom plate 251 of the lower bracket 25 of the heat sink bracket 2 and the opening 131 of the mounting portion 13 the top wall 12 of the shielding shell 1, the pressing spring 64 is abutted against between the base 62 and the front end 631 of the pressing member 63, the contacting spring 65 is provided below the base 62 and is positioned in the inserting passageway 11, when the connector 5 inserts into the inserting passageway 11 and pushes the rear end 632 of the pressing member 63, the pressing member 63 generates downwardly pivoting of the front end 631 and the front end 631 downwardly presses against the pressing spring 64, in turn the pressing spring 64 presses against the contacting spring 65 via the base 62 so as to make the heat sink 6 contact the connector 5, thereby achieving tightly contacting between the heat sink 6 and the connector 5.

As described above, in the present disclosure, provision of the first locking member 41 and the second locking member 42 of the locking construction 4 makes locking and releasing of the locking construction 4 not be limited by the assembling and detaching direction of the snapping member 3, so that the heat sink bracket 2 is more easily assembled and detached, moreover, provision of the first snapping members 31 and the second snapping members 32 of the snapping construction 3, for example, a structure that the snapping pieces 321 are formed by the partitioning wall 15, also make the heat sink bracket 2 adapted to the shielding shell 1 which has a plurality of inserting passageways 11 and needs to be assembled with a plurality of heat sink brackets 2, so the object of the present disclosure can be indeed achieved.

In addition, in the present disclosure, based on assembling of the upper bracket 24 and the lower bracket 25 of the heat sink bracket 2, provision of the position-limiting structure 7 provides position-limiting of the upper bracket 24 and the lower bracket 25 in various directions, which achieves to increase an assembling strength between the upper bracket 24 and the lower bracket 25 and provide a firmly assembled structure.

However, the above description is only for the embodiment of the present disclosure, and it is not intended to limit the implementing scope of the present disclosure, and the simple equivalent changes and modifications made according to the claims and the contents of the specification are still included in the scope of the present disclosure.

What is claimed is:

1. A connector assembly, comprising:
a shielding shell comprising at least one inserting passageway, a top wall which corresponds to the inserting passageway, and a mounting portion which is provided to the top wall;
a heat sink bracket which is allowed to be mounted to the mounting portion of the top wall, the heat sink bracket comprising a side frame portion and a bottom frame portion;
a snapping construction which is provided to the side frame portion of the heat sink bracket and the mounting portion of the top wall and allows the side frame portion of the heat sink bracket to be assembled to the mounting portion; and
a locking construction comprising a first locking member which is provided to the bottom frame portion of the heat sink bracket and a second locking member which is provided to the mounting portion, the first locking member comprising an elastic arm and a locking portion and a locking release portion which are provided to the elastic arm, the locking portion of the first locking member locking to the second locking member, the locking release portion being capable of being operated to make the locking portion leave the second locking member.

2. The connector assembly of claim 1, wherein
the elastic arm is a cantilevered elastic plate structure, is positioned to a rear end of the bottom frame portion of the heat sink bracket and extend rearwardly,
the locking portion is formed to the elastic arm by the elastic arm being stamped to protrude downwardly,
the locking release portion is a levering piece which extends from the elastic arm obliquely in a lateral direction of the elastic arm and in an up-down direction, the levering piece and the top wall of the shielding shell form an inserting space therebetween.

3. The connector assembly of claim 1, wherein
the snapping construction comprises a first snapping member which is provided to the side frame portion of the heat sink bracket, and a second snapping member which is provided to the mounting portion,
the first snapping member is capable of snapping to the second snapping member along a snapping direction which is in a front-rear direction so as to make the second snapping member provide position-limiting to the heat sink bracket both in an up-down direction and in the snapping direction,
the second snapping member is positioned to an outer side of the side frame portion of the heat sink bracket, and is positioned to an outer side of the first snapping member, the second snapping member provides position-limiting to the heat sink bracket in a left-right direction.

4. The connector assembly of claim 3, wherein
the mounting portion comprises two side portions which are respectively positioned left and right,
the first snapping member comprises a plurality of snapping protrusions which protrude outwardly from the side frame portion of the heat sink bracket,
the second snapping member comprises a plurality of snapping pieces which extend upwardly from each side portion of the mounting portion, each snapping piece has a snapping groove opened toward the front,
each snapping protrusion rearwardly snaps into the snapping groove of the snapping piece.

5. The connector assembly of claim 4, wherein
each snapping groove has an inner top edge and an inner bottom edge, and the inner top edge and the inner bottom edge are staggered with each other in the left-right direction, so that when the snapping protrusion inserts into the snapping groove of the snapping piece, positions that the inner top edge and the inner bottom edge abut against the snapping protrusion are staggered with each other in the left-right direction.

6. The connector assembly of claim 5, wherein
the heat sink bracket comprises the two side frame portions which are respectively positioned left and right,
positions of the first snapping members, which are positioned to the two side frame portions of the heat sink bracket, are staggered with each other in the left-right direction.

7. The connector assembly of claim 1, wherein
the heat sink bracket is used to receive a heat sink and further comprises a top frame portion,
the top frame portion comprises two supporting frame borders which are spaced apart from each other and cooperate to define an upper frame mouth, and a transverse frame bar which connects the two supporting frame borders,
the upper frame mouth allows the heat sink to upwardly extend out therefrom,
the transverse frame bar is positioned between a plurality of heat dissipating fins of the heat sink, and is used to limit a position of the heat sink in a front-rear direction.

8. The connector assembly of claim 1, wherein
the side frame portion of the heat sink bracket is provided with apertures, the apertures correspond to airflow passageways between heat dissipating fins of the heat sink.

9. The connector assembly of claim 1, wherein
the side frame portion of the heat sink bracket is provided with a plurality of guiding protrusions which are toward the down,
a side portion of the mounting portion is provided with elongated guiding holes which each allows to the respective guiding protrusion to enter therein, and a length of each elongated guiding hole in the front-rear direction is larger than the respective guiding protrusion.

10. A connector assembly, comprising:
a heat sink bracket assembled by an upper bracket and a lower bracket, the upper bracket comprising a top plate and two first side plates which are respectively positioned left and right, the lower bracket comprising a bottom plate and two second side plates which are respectively positioned left and right, the top plate of the upper bracket constituting a top frame portion of the heat sink bracket, the bottom plate of the lower bracket constituting a bottom frame portion of the heat sink bracket, each first side plate of the upper bracket and the corresponding second side plate of the lower bracket overlapping with each other and constituting one side frame portion of the heat sink bracket; and
a position-limiting structure comprising a first position-limiting portion and a second position-limiting portion which are provided to each first side plate of the upper bracket and a third position-limiting portion and a fourth position-limiting portion which are provided to each second side plate of the lower bracket, the first position-limiting portion and the third position-limiting portion providing position-limiting in a first direction, the second position-limiting portion and the fourth position-limiting portion providing position-limiting in a second direction.

11. The connector assembly of claim 10, wherein
in the first side plate and the second side plate which overlap with each other, the first side plate is positioned outside, the second side plate is positioned inside,
the first position-limiting portion comprises a latching hole which is provided to the first side plate, the third position-limiting portion comprises a latching protrusion which is provided to the second side plate.

12. The connector assembly of claim 11, wherein
the first position-limiting portion comprises the two latching holes which are provided respectively in the front of the first side plate and at the rear of the first side plate,
the third position-limiting portion comprises the two latching protrusions which are provided respectively in the front of the second side plate and at the rear of the second side plate and respectively correspond to the two latching holes,
each latching hole is larger than the corresponding latching protrusion,
a front edge and a bottom edge of the latching hole which is positioned in the front of the first side plate is capable of being limited in position by the corresponding latching protrusion, and a rear edge and a bottom edge of the latching hole which is positioned at the rear of the first side plate is capable of being limited in position by the corresponding latching protrusion, thereby providing position-limiting both in a front-rear direction and in an up-down direction.

13. The connector assembly of claim 10, wherein
the first side plate is positioned outside, the second side plate is positioned inside,
the second position-limiting portion comprises a depressed portion which is positioned to the first side plate and is depressed inwardly,
the fourth position-limiting portion comprises a protruding portion which is positioned to the second side plate, the protruding portion is constructed on an upper edge of a protruding part, which is outward, of the second side plate and extends upwardly, the protruding portion enters into the depressed portion, the protruding portion is positioned to an outer side of the depressed portion in a left-right direction and the protruding portion and the depressed portion stop each other in the left-right direction.

14. The connector assembly of claim 10, wherein
the position-limiting structure further comprises a stopping tab which is provided to the upper bracket,
the stopping tab extends downwardly from the top plate of the upper bracket and is positioned to an inner side of the first side plate, so that a top edge of the second side plate is positioned between the first side plate and the stopping tab, thereby providing position-limiting of an upper end of the second side plate in a left-right direction.

15. The connector assembly of claim 10, wherein
the connector assembly further comprises a shielding shell, the shielding shell comprises at least one inserting passageway, a top wall which corresponds to the inserting passageway, and a mounting portion which is provided to the top wall;
each side frame portion of the heat sink bracket and the mounting portion are provided therebetween with a first snapping member and a second snapping member which cooperate with each other;
the bottom plate of the lower bracket and the mounting portion are provided therebetween with a first locking member and a second locking member which cooperate with each other.

16. The connector assembly of claim 15, wherein
the first locking member comprises an elastic arm and a locking portion and a locking release portion which are provided to the elastic arm, the locking portion of the first locking member locks to the second locking member, the locking release portion is capable of being operated to make the locking portion leave the second locking member.

17. The connector assembly of claim 16, wherein
the elastic arm is a cantilevered elastic plate structure, is positioned to a rear end of the bottom frame portion of the heat sink bracket and extend rearwardly,
the locking portion is formed to the elastic arm by the elastic arm being stamped to protrude downwardly,
the locking release portion is a levering piece which extends from the elastic arm obliquely in a lateral direction of the elastic arm and in an up-down direction, the levering piece and the top wall of the shielding shell form an inserting space therebetween.

18. The connector assembly of claim 16, wherein
the first snapping member is provided to the side frame portion of the heat sink bracket, the second snapping member is provided to the mounting portion,
the first snapping member is capable of snapping to the second snapping member along a snapping direction which is in a front-rear direction so as to make the second snapping member provide position-limiting to the heat sink bracket both in an up-down direction and in the snapping direction,
each second snapping member is positioned to an outer side of the side frame portion of the heat sink bracket, and is positioned to an outer side of the first snapping member, the second snapping members provide position-limiting to the heat sink bracket in a left-right direction.

19. The connector assembly of claim 18, wherein
the mounting portion comprises two side portions which are respectively positioned left and right,
the first snapping member comprises a plurality of snapping protrusions which protrude outwardly from the side frame portion of the heat sink bracket,
each second snapping member comprises a plurality of snapping pieces which extend upwardly from each side portion of the mounting portion, each snapping piece has a snapping groove opened toward the front,
each snapping protrusion rearwardly snaps into the snapping groove of the snapping piece.

20. The connector assembly of claim 18, wherein
each snapping groove has an inner top edge and an inner bottom edge, and the inner top edge and the inner bottom edge are staggered with each other in the left-right direction, so that when the snapping protrusion inserts into the snapping groove of the snapping piece, positions that the inner top edge and the inner bottom edge abut against the snapping protrusion are staggered with each other in the left-right direction.

21-24. (canceled)
